(19) United States
(12) Patent Application Publication
(10) Pub. No.: US 2002/0109089 A1
(43) Pub. Date: Aug. 15, 2002

(54) SEM provided with an adjustable final electrode in the electrostatic objective

(76) Inventors: Jan Martijn Krans, Eindhoven (NL); Sander Gijsbert Den Hartog, Eindhoven (NL); Marcellinus Petrus Carolus Michael Krijn, Eindhoven (NL)

Correspondence Address: Michael E. Marion, c/o U.S. PHILIPS CORPORATION, Intellectual Property Department, 580 White Plains Road, Tarrytown, NY, 10591, US

(21) Appl. No.: 10/043,389

(22) Filed: Oct. 26, 2001

(30) Foreign Application Priority Data
Oct. 31, 2000 (EP) 00203786.9

(51) Int. Cl. H01J 37/256

(52) U.S. Cl. 250/310

(57) ABSTRACT

A SEM with an electrostatic objective lens 14, 16 and a detector 6, 8 for through-the-lens detection of secondary electrons (SEs) 24. A suitable collection efficiency of the SEs would require a comparatively high electric field near the surface of the specimen 18, whereas suitable voltage contrast (voltage range of the order of from 1 to 5 V) would require a moderate electric field near the surface of the specimen. In accordance with the invention an adjustable voltage source is provided in order to adjust at will the voltage of the final electrode 16 relative to the specimen, such that the voltage contrast and the collection efficiency can be adjusted to an optimum value in conformity with the measurement requirements.

### The invention relates to a particle-optical apparatus which includes

a particle source for producing a primary beam of electrically charged particles which travel along an optical axis of the apparatus,

a specimen holder for a specimen to be irradiated by means of the apparatus,

a focusing device for forming a focus of the primary beam in the vicinity of the specimen holder by means of electrostatic electrodes,

detection means for detecting electrically charged particles which emanate from the specimen in response to the incidence of the primary beam, which detection means are arranged ahead of the focusing device, viewed in the propagation direction of the electrically charged particles in the primary beam,

and an electrostatic final electrode which is arranged directly ahead of the specimen holder, viewed in the propagation direction of the electrically charged particles in the primary beam.

An apparatus of this kind is known from the published international patent application WO 99/34397. In the apparatus described therein a region of a specimen to be examined is scanned by means of a primary focused beam of electrically charged particles, usually electrons, which travel along an optical axis of the apparatus. An apparatus of this kind is known as a Scanning Electron Microscope (SEM).

Irradiation of the specimen to be examined releases electrically charged particles, such as secondary electrons, from the specimen, said particles having an energy which is significantly lower than that of the particles in the primary beam, for example of the order of magnitude of from 1 to 5 eV. The energy and/or the energy distribution of such secondary electrons provides information as regards the nature and composition of the specimen. Therefore, it is useful to provide a SEM with a detection device (detector) for secondary electrons. Such electrons are released at the side of the specimen at which the primary beam is incident, after which they travel back against the direction of incidence of the primary electrons. When a detector (for example, provided with an electrode carrying a positive voltage) is arranged in the path of the secondary electrons thus traveling back, the secondary electrons are captured by this electrode and the detector outputs an electric signal which is proportional to the electric current thus detected. The (secondary electron) image of the specimen is thus formed in known manner. With a view to the quality of the image, notably the speed at which the image is formed and the signal-to-noise ratio, the detected current is preferably as large as possible, that is, the detection efficiency of the secondary electrons is preferably in the vicinity of 100%.

Nowadays there is a tendency to construct SEMs to be as small as possible. Apart from economical motives (generally speaking, smaller apparatus can be more economically manufactured), such small apparatus offer the advantage that, because of their mobility and small space required, they can be used not only as a laboratory instrument but also a tool for the formation of small structures, for example as in the production of integrated circuits. In this field a miniaturized SEM can be used for direct production as well as for inspection of products. With a view to direct production, the SEM can be used to write, using electrons, a pattern on the IC to be manufactured. With a view to the inspection application, the SEM can be used to observe the relevant process during the writing by means of a further particle beam (for example, an ion beam for implantation in the IC to be manufactured), it also being possible to use the SEM for on-line inspection of an IC after execution of a step of the manufacturing process.

For miniaturization of a SEM it is attractive to use an electrostatic objective, because such an objective can be constructed so as to be smaller than a magnetic lens. This is due to the fact that cooling means (notably cooling ducts for the lens coil) can be dispensed with and that the magnetic (iron) circuit of the lens requires a given minimum volume in order to prevent magnetic saturation. Moreover, because of the contemporary requirements as regards high vacuum in the specimen space, electrostatic electrodes (which are constructed as smooth metal surfaces) are more attractive than the surfaces of a magnetic lens which are often provided with coils, wires and/or vacuum rings. Finally, as is generally known in particle optics, an electric field is a more suitable lens for heavy particles (ions) than a magnetic field. The objective in the known SEM has two electrostatic electrodes which together constitute a decelerating system for the primary beam.

The arrangement of the detector for the secondary electrons ahead of the focusing device in the known SEM offers the advantage that when the SEM is used for the observation of ICs, it is also easier to look into pit-shaped irregularities; this is because observation takes place along the same line as that along which the primary beam is incident. Moreover, arranging a detector to the side of the objective and directly above the specimen would have the drawback that the detector would then make it impossible to make the distance between the objective and the specimen as small as desirable with a view to the strong reduction of the electron source necessary to achieve a size of the scanning electron spot which is sufficiently small with a view to the required resolution. Furthermore, when an electrostatic objective is used in a SEM, it often happens that the electrostatic lens field of the objective extends beyond the physical boundaries of the objective, so possibly as far as the specimen. (This electric field between the final electrode of the objective and the specimen is also referred to as the leakage field). Secondary electrons emanating from the specimen are attracted by said leakage field. A detector arranged, for example to the side of the objective should then require a much stronger attractive effect, so that the primary beam would be influenced to an inadmissible extent. This drawback is avoided by arranging the detector above the objective. After the secondary electrons attracted by the leakage field have passed through the bore of the objective, the electric field present at that area accelerates said secondary electrons to an energy value which corresponds to the potential in the space ahead of the objective. The electrons thus accelerated then have an energy that suffices so as to excite the detector material, thus enabling detection.

In the SEM that is known from the cited international patent application WO 99/34397 the electrode of the objective that is arranged nearest to the specimen holder is formed by said electrostatic final electrode which is arranged directly ahead of the specimen holder as viewed in the propagation direction of the electrically charged particles in the primary beam. The cited patent document, however, does not disclose information as regards the potential of this final electrode; however, this final electrode customarily has the same potential as the specimen to be irradiated by means of the SEM.

For the examination of a specimen it is often desirable that voltage contrast can be observed, that is, that regions of the specimen of mutually different potential (for example, of the order of magnitude of some volts) exhibit a different intensity in the image, so that contrast arises between these regions. This is particularly desirable for the examination of integrated circuits in which the presence of defects becomes manifest as the presence or absence of voltage differences across the circuit. The contrast arises as follows. As is known, most secondary electrons emanating from the surface of the specimen have an energy of between 0 and 10 eV. However, in case a region on the specimen surface exhibits a given voltage (for example, an electrode in a semiconductor circuit) such secondary electrons should have a corresponding minimum energy so as to enable them to emanate from the surface in said region. This means that all secondary electrons having an energy that is less than said amount cannot emanate and hence cannot contribute to the overall secondary electron current. For example, an electron that is activated by the primary beam with an energy of, for example 5 eV in a specimen region with a voltage of, for example 3 V, can emanate from the surface, but an electron having an energy of, for example 2 eV in said specimen region cannot leave the surface. The overall secondary electron current from a given region, therefore, will be dependent on the voltage of the relevant specimen region. This will create a difference in intensity between different voltage regions.

Another important aspect of the observation of the specimen is formed by the collection efficiency, that is, the fraction of the total number of emitted secondary electrons that ultimately contributes to the detected signal. Because of the signal-to-noise ratio in the image, it is desirable to detect a given minimum number of electrons per pixel of the image, but because the building up of an image of the specimen must take place within a reasonably short period of time during a scan of the primary beam (preferably of the order of magnitude of seconds instead of hours), it is not possible for the observation of a pixel to last very long. This means that as few as possible secondary electrons should be lost to detection. Electrons can be lost to detection, for example because of their energy distribution, so that electrons having a comparatively high thermal energy escape from the collecting field. Collisions between secondary electrons themselves, collisions with residual gas ions or a small exit angle from the specimen may also enable secondary electrons to escape from the collecting field. In order to counteract this adverse effect, it would be desirable to employ a strong collecting field, that is, for example a field of the order of magnitude of 100 V.

It will be understood that the need for a suitable voltage contrast is not very compatible with the need for a high collection efficiency.

It is an object of the invention to provide a particle-optical apparatus of the kind set forth in which the requirements as regards high collection efficiency and a suitable voltage contrast can both be satisfied. To this end, the apparatus in accordance with the invention is characterized in that the apparatus is provided with power supply means for adjusting a potential difference between the specimen to be irradiated by means of the apparatus and the final electrode.

The invention is based on the recognition of the fact that in order to realize a suitable observation situation it is necessary to find an optimum between a suitable voltage contrast and a suitable collection efficiency, and that this optimum will be dependent on the nature of the specimen to be examined, on the observation situation (for example, the specimen tilted relative to the primary beam or extending perpendicularly thereto, observation on a flat surface or in a pit-like recess in the specimen) or on other observation parameters. Because the voltage of the final electrode is made adjustable, for each observation, for example a suitable voltage contrast can be searched for which the signal-to-noise ratio is not yet degraded to a significant extent. For example, when details on the bottom of a pit-like recess are observed (with an aspect ratio of, for example, 4:1), in comparison with the case where details are observed on the surface of the specimen a much higher voltage will be required on the specimen surface so as to create a collecting field on the bottom of the pit that is adequate to collect the secondary electrons from the bottom of the pit. In the case of a tilted specimen the collecting field may be distorted by tilting to such an extent that compensation must be provided by changing the potential of the final electrode.

The final electrode in a preferred embodiment of the invention is formed by the electrode of the focusing the device that is situated nearest to the specimen holder. The space between the objective and the specimen is thus left completely available for movement of the specimen relative to the primary beam, that is, notably tilting of the specimen.

The final electrode in another embodiment of the invention is formed by an electrode which is situated between the electrode of the focusing device that is nearest to the specimen holder and the specimen holder, said electrode being rotationally symmetrical around the optical axis. Even though some freedom as regards the specimen motion is thus surrendered, it is achieved that adjustment of the voltage across the final electrode enables adjustment of the electric field at the area of the specimen surface as desired, without the optical properties of the objective being modified. This step also offers advantages for the detection of secondary electrons emanating from the bottom of a pit-like recess in the specimen. In order to enable such electrons to be attracted from this pit-like recess, a comparatively high voltage of the final electrode is required, for example a voltage of 1 V in the case of a distance of 1 mm from the specimen. If this voltage were applied to the last electrode of the objective, the optical properties thereof would be affected to an undesirable degree. Moreover, this additional electrode has a given lens effect in combination with the final electrode of the objective, so that the returned beam of secondary electrons has a focal point at the area of the objective and hence a comparatively large cross-section at the area of the detector surface. It is thus avoided that a major part of this narrow beam is radiated back through the opening in the detector, so that this beam would not be detected.

In another embodiment yet of the invention the final electrode is symmetrically subdivided into a number of electrically isolated segments around the optical axis. This enables further influencing of the beam of secondary electrons. The secondary beam can thus be subjected to a deflecting action by subdividing the final electrode into two or more segments so that a dipole field can be superposed on the original rotationally symmetrical electric field. The effect thereof consists in that the secondary beam is directed slightly obliquely through the opening of the objective, so that it is also avoided that this beam is radiated back to a substantial degree through the opening in the detector so that this beam would no longer be detected. The secondary beam can now be directed completely to the side of the opening in the detector on the detector surface, so that substantially the entire electron current in the secondary beam is detected.

In another embodiment yet of the invention the final electrode is formed by an electrode which is situated between the electrode of the focusing device that is situated nearest to the specimen holder and the specimen holder, said final electrode being situated completely to one side of the optical axis. As will be demonstrated on the basis of one of the embodiments in accordance with the invention, such a construction offers special advantages with a view to the distribution of the electric collecting field in the case of tilted specimens, without the advantage of freedom of movement of the specimen being lost.

The invention will be described in detail hereinafter with reference to the Figures in which corresponding reference numerals denote corresponding elements. Therein:

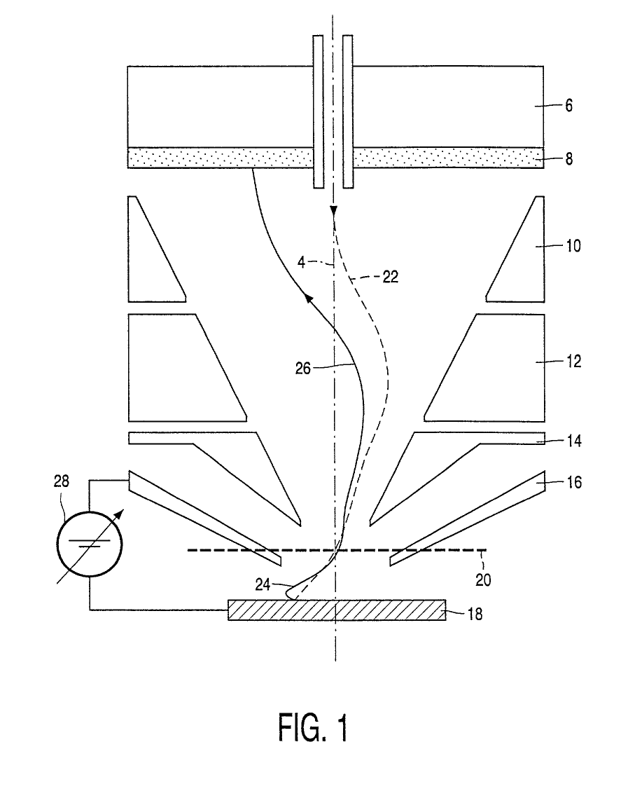

FIG. 1 is a diagrammatic representation of a relevant part of a particle-optical apparatus in accordance with the invention;

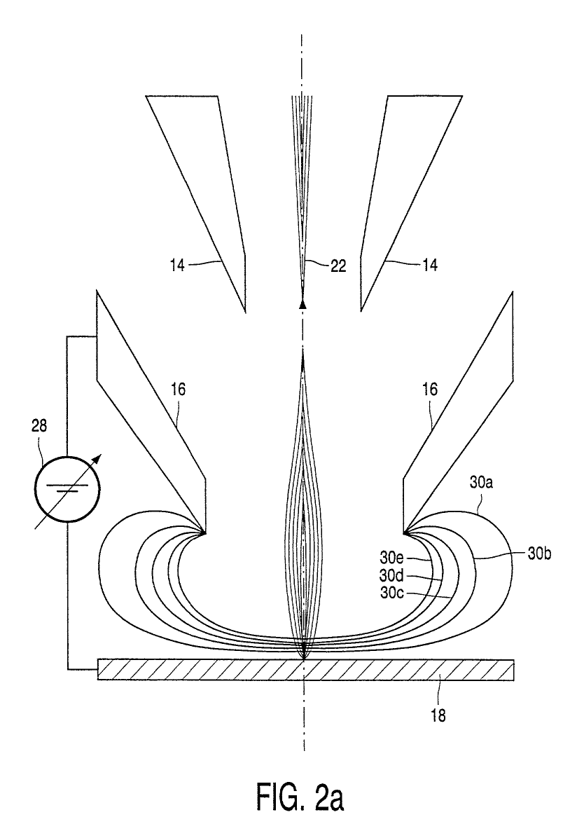

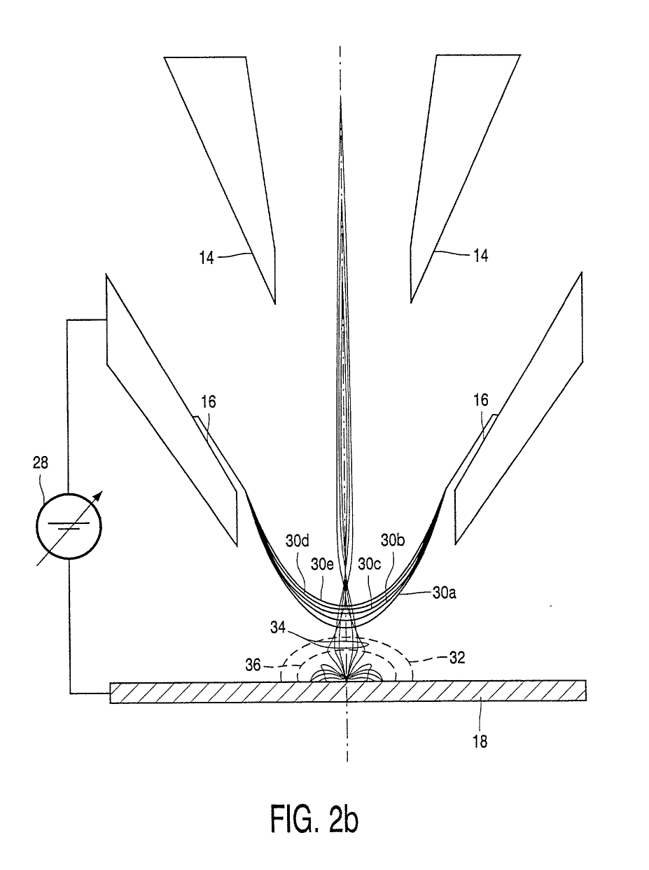

FIG. 2a illustrates the distribution of the electric field outside the electrode structure of an objective in a known particle-optical apparatus;

FIG. 2b illustrates the distribution of the electric field outside the electrode structure of an objective as shown in FIG. 1;

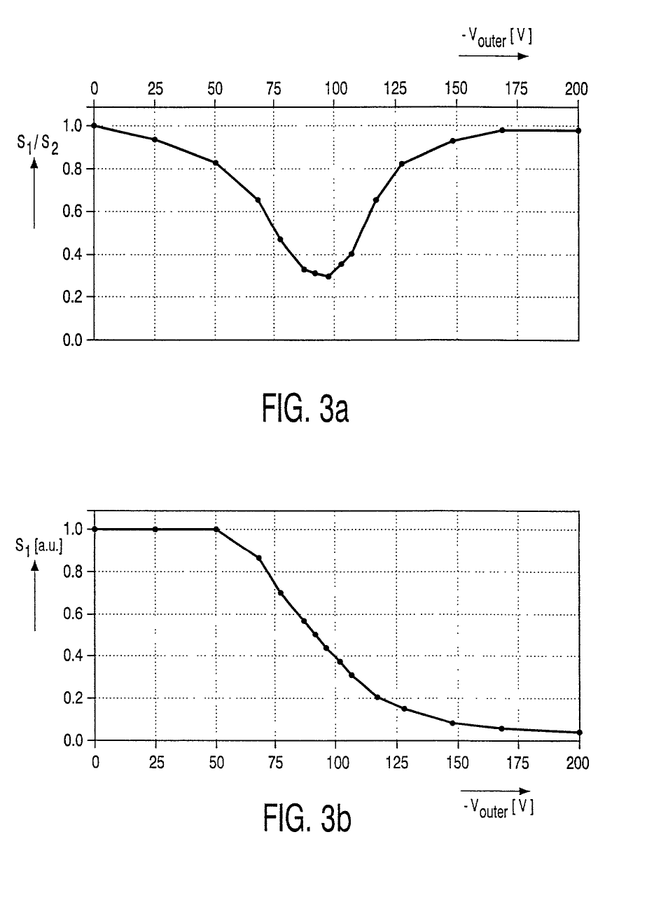

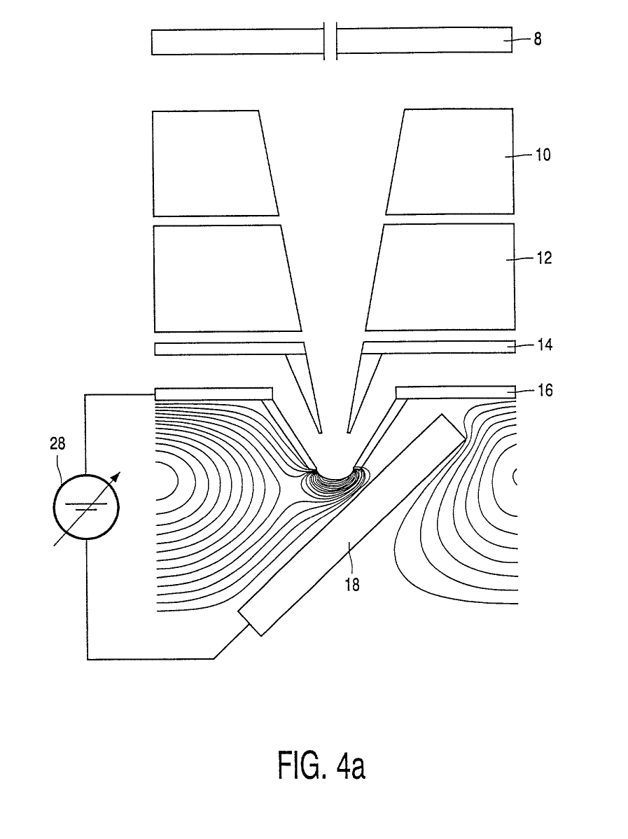

FIG. 3a is a graphic representation of the measured voltage contrast of secondary electrons in a particle-optical apparatus in accordance with the invention;

FIG. 3b is a graphic representation of the measured detection efficiency of secondary electrons in a particle-optical apparatus in accordance with the invention;

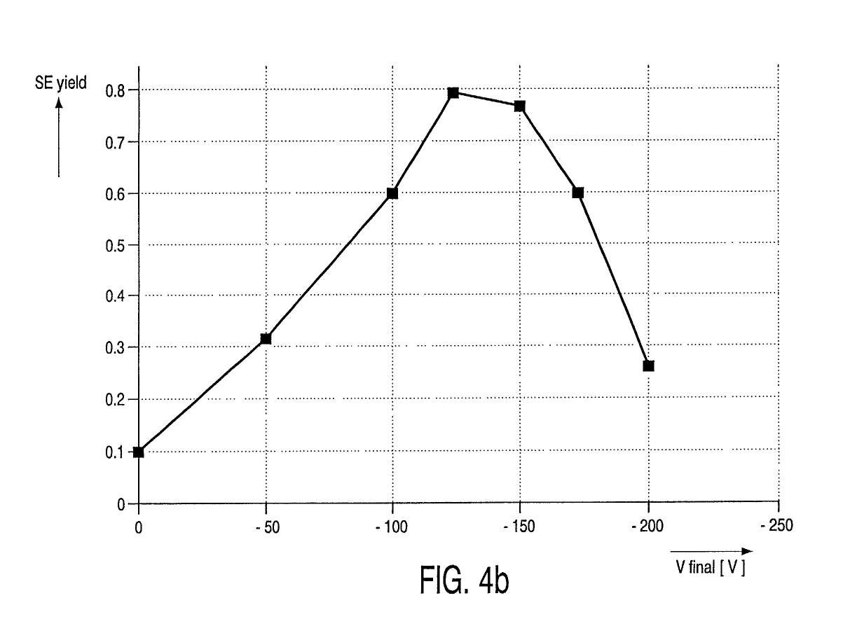

FIG. 4a shows diagrammatically the field distribution in the vicinity of a tilted specimen in a particle-optical apparatus in accordance with the invention;

FIG. 4b is a graphic representation of the simulated detection efficiency of secondary electrons in a particle-optical apparatus as shown in FIG. 4a;

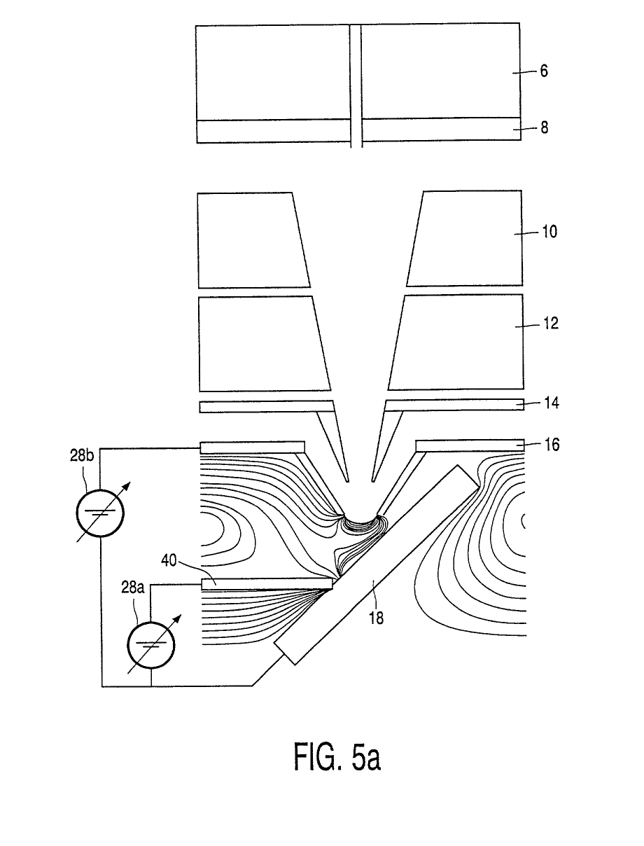

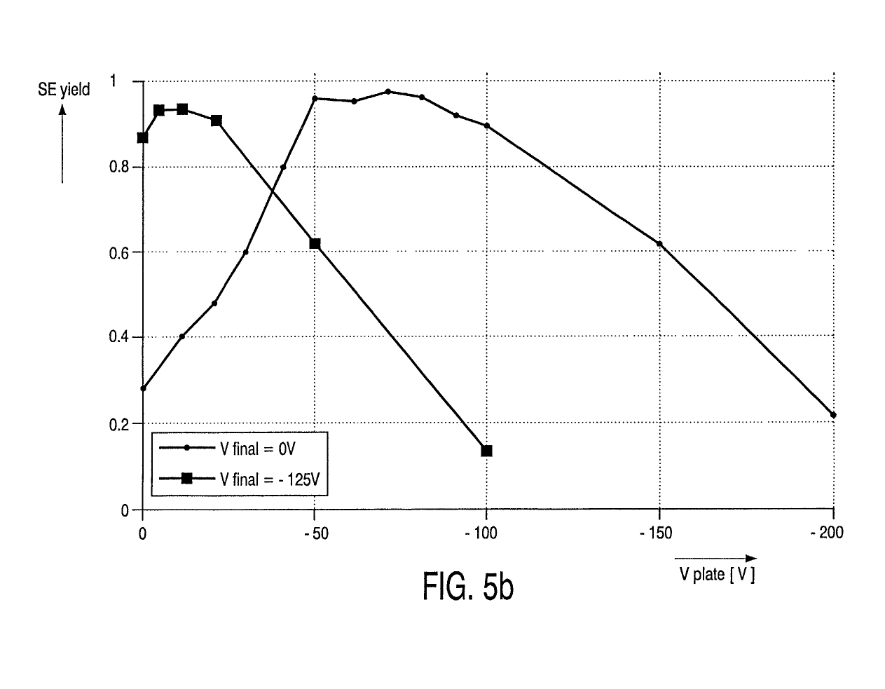

FIG. 5a is a diagrammatic representation of the field distribution in the vicinity of a tilted specimen and a plate-shaped electrode in a particle-optical apparatus in accordance with the invention;

FIG. 5b is a graphic representation of the simulated detection efficiency in a particle-optical apparatus as shown in FIG. 5a, and

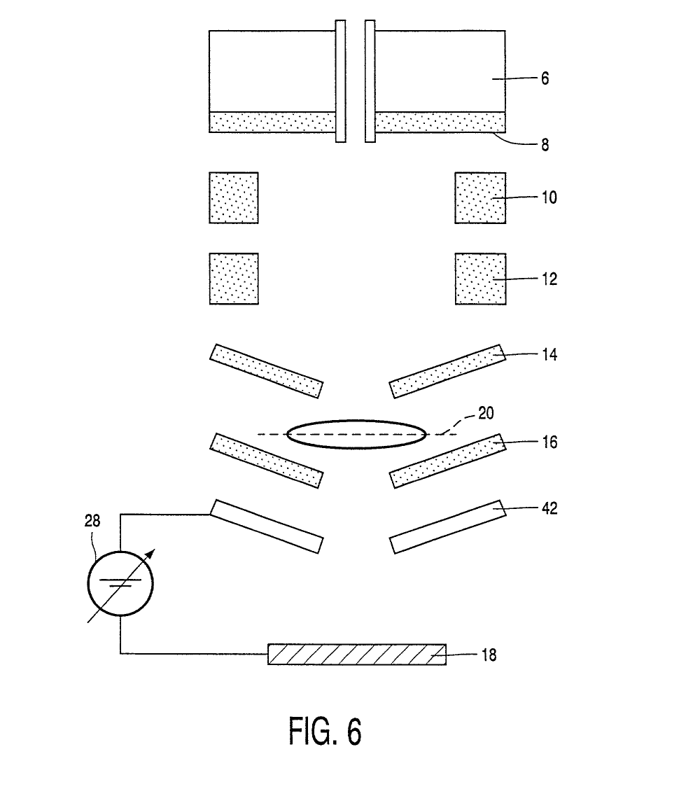

FIG. 6 shows an embodiment of the invention which includes a rotationally symmetrical final electrode that is arranged between the objective and the specimen.

FIG. 1 shows a relevant part of a SEM in accordance with the invention. In as far as they are not relevant to the invention, the electron source and all further elements that form part of the electron-optical column and serve to accelerate and control the primary beam are not shown. The primary beam, which is not shown in FIG. 1, travels along the optical axis 4 of the SEM. The primary beam then successively traverses a detector crystal 6, an electrostatic acceleration electrode 8, a first electrical deflection electrode 10, a second electrical deflection electrode 12, a first electrostatic electrode 14 which forms part of the objective, and a second electrostatic electrode 16 which also forms part of the objective. Finally, the electrons of the primary beam reach the specimen 18 to be examined or worked.

The detector crystal 6 forms part of detection means for the detection of electrons emanating from the specimen in response to the incidence of the primary beam. This detector crystal consists of a substance (for example, cerium-doped yttrium aluminum garnet or YAG) which produces a light pulse in response to the capture of an electron of adequate energy; this light pulse is conducted further by means of optical guide means (not shown) and is converted, in an opto-electronic converter, into an electrical signal wherefrom an image of the specimen can be derived, if desired. The latter elements also form part of said detection means. The detector crystal is provided with a bore for the passage of the primary beam.

The electrostatic acceleration electrode 8 forms part of the electrode system 8, 14, 16, the electrodes 14 and 16 of which constitute the objective of the SEM which serves to focus the primary beam. The electrode 8 is shaped as a flat plate which is provided with a bore for the primary beam and is deposited on the detection material in the form of a conductive oxide, for example indium and/or tin oxide, notably on the detection surface of the scintillation crystal 6. The electrode 8 can be adjusted to a desired voltage, for example 9 kV, by means of a power supply unit (not shown).

The first electrical deflection electrode 10 and the second electrical deflection electrode 12 form part of a beam deflection system for deflecting the primary beam. Each of these two electrodes is constructed as a tubular portion having an external shape in the form of a straight circular cylinder and an internal shape in the form of a cone which is tapered in the direction of the beam. Each of the electrodes 10 and 12 is subdivided, by way of two saw cuts in mutually perpendicular planes through the optical axis, into four equal parts so that each of the electrodes 10 and 12 is capable of producing electric dipole fields in the x direction as well as in the y direction by application of suitable voltage differences between the parts, so that the primary beam can be deflected across the specimen 18 and the path of the secondary electrons moving in the direction of the detector crystal can be influenced. Instead of subdividing the electrodes 10 and 12 into four parts, they can also be subdivided into a larger number of parts, for example eight equal parts, by means of four saw cuts in a plane through the optical axis. By application of the appropriate voltages to the various parts of each of the electrodes, the system thus formed can be used not only for deflecting the beam but also as a stigmator.

The first electrode 14 and the second electrode 16 constitute the electrode system which forms the objective of the SEM. Internally as well as externally the electrode 14 is shaped as a cone which is tapered downwards, so that this electrode fits within the electrode 16. Internally as well as externally the electrode 16 is also shaped as a cone which is tapered downwards; the external conical shape offers optimum space for the treatment of comparatively large specimens such as circular wafers which are used for the manufacture of ICs and may reach a diameter of 300mm. Because of the external conical shape of the electrode 16, the primary beam can be made to strike the wafer at a comparatively large angle by tilting the wafer underneath the objective, without the wafer being obstructed by parts projecting from the objective. A dashed line 20 in the Figure indicates the region in which the lens effect of the electric objective field (so the paraxial center of the objective) can be assumed to be localized.

The objective 14, 16 focuses the primary beam in such a manner that the electron source is imaged on the (grounded) specimen with a generally very large reduction; because of this strong reduction, the distance between the surface of the specimen 18 and the center of the lens 20 (the focal distance) is very small which, as has already been mentioned, would severely limit the possibility of tilting if the external shape of the electrode 16 were not conical.

The Figure shows the course of some electron paths in the particle-optical instrument. The course of these paths has been obtained by way of computer simulation; the following assumptions were made for this simulation: the voltage whereby the primary beam is accelerated amounted to 10 kV; the energy of the secondary electrons is 1 eV; the specimen is grounded; the voltage V_{d} at the detector amounts to 9 kV; the voltages at the electrode 10 are 9+2=11 kV and 9−2=7 kV; the voltages at the electrode 12 are 9−1.8=7.2 kV and 9+1.8=10.8 kV. In the rendition of the electron courses in the Figure the electrode 16 carries the same potential as the specimen 18.

The primary beam 22 (only diagrammatically represented by a dashed line in this Figure) entering the assembly formed by the detector, the deflection electrodes and the objective initially travels along the optical axis 4. Under the influence of the electric deflection field generated by the electrode 10, the beam is deflected away from the axis, after which it is deflected towards the axis again under the influence of the opposed deflection field that is generated by the electrode 12. As a result, the primary beam intersects the optical axis far below the deflection electrodes 10 and 12. As a result of the arrangement of and the fact that the beam deflection system operates with two opposite fields it is achieved that the tilting point is situated in the central plane 20 of the objective, so that a large field of view and a minimum imaging error are achieved, regardless of the magnitude of the scanning motion of the primary beam. This phenomenon can be clearly observed in the Figure which shows that, after deflection by the deflection fields, the primary beam intersects the optical axis 4 in the central plane 20.

The incidence of the primary beam 22 on the specimen 18 releases secondary electrons from the specimen which travel upwards under the influence of the electric field of the objective, of the deflection system and of the detector voltage. The Figure shows a path 24 of such a secondary electron. The secondary electron is pulled into the bore of the objective, after which it becomes subject to the deflector fields. The Figure illustrates the effect of the electric deflection fields by way of the path 26.

Between the electrode 16 and the specimen 18 there are arranged power supply means for adjusting a potential difference between the specimen 18 to be irradiated by means of the apparatus and the electrode 16, said means being formed by an adjustable voltage source 28.

FIG. 2a shows the distribution of the electric field outside the electrode structure of the objective in a known particle-optical apparatus, that is, in a situation in which the electrode 16 carries the same potential as the specimen. For the sake of clarity the primary beam has been omitted in this Figure, but this beam is focused onto the specimen 18. The beam 22 of secondary electrons is diagrammatically shown in the figure. This beam leaves the specimen 18 in a small region around the focal point of the primary beam and is focused within the objective 14, 16 while traveling upwards. The initial energy of the secondary electrons is assumed to be 5 eV. In this Figure the excitation of the object amounted to 12 kV. The figure shows five equipotential lines 30a, 30b, 30c, 30d and 30e which represent a potential of 2 V, 4 V, 6 V, 8 V and 10 V, respectively. This Figure clearly shows that a potential of the order of magnitude of 10 V is present across the surface of the specimen 18. Consequently, practically all secondary electrons are pulled into the objective so that a high collection efficiency is achieved. FIG. 2b shows the distribution of the electric field outside the electrode structure of an objective as shown in FIG. 1, the electrode 16 being adjusted to a potential of −100 V. The excitation of the objective amounted to 12 kV in this Figure. The primary beam has been omitted for the sake of clarity of this Figure, but it is also focused onto the specimen 18. This Figure again shows five equipotential lines 30a, 30b, 30c, 30d and 30e which represent a potential of 2 V, 4 V, 6 V, 8 V and 10 V, respectively. In the situation shown herein these lines are situated substantially further from the specimen surface. Consequently, the secondary electrons (whose paths are shown within the region 32) can travel only partly in the direction of the electrode 16; these are the secondary electrons which emanate from the specimen surface at a comparatively large angle. The paths of these electrons are denoted by the reference numeral 34 in the Figure. Other secondary electrons emanate from the specimen surface at an angle which is not large enough to impart adequate energy to these electrons in the direction of the collecting field and the electrode 16. These secondary electrons return to the specimen and hence do not participate in the imaging. The paths of these secondary electrons are denoted by the reference numeral 36 in the Figure.

FIG. 3a is a graphic representation of the measured voltage contrast in a particle-optical apparatus in accordance with the invention whereas FIG. 3b is a graphic representation of the detection efficiency then measured in the particle-optical apparatus. These two Figures have been obtained as follows. A specimen to be examined is provided with conductive strips, one of which is adjusted to a voltage of 0 V whereas the other is adjusted to a voltage of +2 V. The intensity of the secondary electrons emanating from the two strips is compared and the voltage contrast is determined on the basis thereof. The voltage across the electrostatic acceleration electrode 8 and across the deflection electrodes amounted to 6 kV while the focusing voltage across the objective amounted to 12 kV. The distance between the final electrode 16 and the point of intersection of the optical axis and the specimen surface amounted to 2 mm. The specimen was not tilted. The voltage across the electrode 16 of the objective is adjustable between 0 V and −200 V. In the context of these Figures the term “voltage contrast” is to be understood to mean the ratio of the electric currents of the secondary electrons emanating from each of said strips. Comparison of the two Figures shows that the most sensitive area for the voltage contrast lies around −100 V (where the ratio of the secondary electron currents from each of said strips has an extreme value); at that value the collection efficiency still amounts to approximately 50%. The detection efficiency is reduced, as is shown in FIG. 3b, by reducing the acceleration of the secondary electrons. During measurements for which it is necessary to achieve a better detection efficiency while less voltage contrast suffices, it is now possible to choose a different, more favorable situation by varying the voltage across the electrode 16.

FIG. 4a shows the field distribution in the vicinity of a tilted specimen 18 in a particle-optical apparatus. The specimen encloses an angle of 45 degrees relative to the optical axis. The voltage across the electrostatic acceleration electrode 8 and across the deflection electrodes 10 and 12 amounted to +10 kV; the focusing voltage across the objective amounted to +12 V. The distance between the final electrode 16 and the point of intersection of the optical axis and the specimen surface amounted to 4 mm. The Figure shows the equipotential lines of the leakage field, that is, all for an electrode voltage of 0 V across the electrode 16. The rotational symmetry of the leakage field is seriously disturbed by the tilting of the specimen, so that the collection efficiency of the secondary electrons is strongly influenced. For example, when the electrode 16 carries the same potential as the specimen (in which case the electrode voltage amounts to 0 V), the collection efficiency of the secondary electrons is of the order of magnitude of 10%. It has been found that in the situation shown the collection efficiency can be enhanced by varying the potential of the electrode 16; the result thereof is shown in FIG. 4b.

FIG. 4b is a graphic representation of the detection efficiency of secondary electrons in the particle-optical apparatus as shown in FIG. 4a; this graph has been obtained by way of computer simulation. In this graph the potential of the electrode 16 is varied between 0 V and −200 V. The fact that the collection efficiency can initially be enhanced by application of a negative potential to the final electrode can be explained by realizing that the deflection effect by said dipole field in the direction away from the direction of the lens opening is thus canceled; the secondary electrons are then pulled less towards the side wall of the final electrode and more towards the opening of the electrode. This demonstrates that the detection efficiency can be considerably enhanced, even in the case of a tilted specimen, by correct adjustment of the potential of the final electrode; the graph shows that even a value of 80% can be reached at an electrode potential of −125 V.

FIG. 5a shows the field distribution in the vicinity of a tilted specimen 18 and a plate-shaped electrode 40 in a particle-optical apparatus. The plate-shaped electrode 40 is arranged completely to one side of the optical axis. It has a straight edge which extends perpendicularly to the plane of drawing. The specimen encloses an angle of 45 degrees relative to the optical axis. The voltage across the electrostatic acceleration electrode 8 and across the deflection electrodes 10 and 12 amounted to +10 kV and the focusing voltage across the objective amounted to +12 V. The distance between the final electrode 16 and the point of intersection of the optical axis and the specimen surface amounted to 4 mm, the plate 40 being situated 5 mm below the lower side of the final electrode and at a distance of 0.1 mm from the specimen surface. This Figure shows the equipotential lines of the leakage field, that is, all for a voltage of 0 V across the electrode 16 and a voltage of −100 V across the plate 40. Like in FIG. 4a, the tilting of the specimen has seriously disturbed the rotational symmetry of the leakage field, but the presence of the plate 40 cancels the deflection effect of the dipole field component so that the collection efficiency of the secondary electrons is enhanced. FIG. 5 shows the result of the foregoing.

FIG. 5b is a graphic representation of the detection efficiency of secondary electrons in the particle-optical apparatus shown in FIG. 5a; this graph has been obtained by way of computer simulation. In this graph the potential of the plate 40 is varied between 0 V and 200 V, that is, for a potential of the electrode 16 of 0 V as well as of −125 V. In the case of a potential of 0 V across the electrode 16, it has been found that the variation of the potential of the plate 40 has an effect which is similar to that of the variation of the voltage across the electrode 16 in FIG. 4b, be it that the voltage values in FIG. 5b are different from those in FIG. 4b because of the smaller distance between the plate 40 and the specimen surface. FIG. 5b also shows that even in the case of a tilted specimen the detection efficiency can be considerably enhanced by correct adjustment of the potential of the final electrode (in this case being the plate 40); the graph shown demonstrates that even a value of approximately 95% can be achieved for a plate potential of −70 V.

FIG. 6 shows an embodiment of the invention in which a rotationally symmetrical final electrode 42 is arranged between the objective and the specimen. The shape of the final electrode 42 may be substantially the same as that of the electrode 16, but it may also be shaped, for example as a flat, round disc. It is thus achieved that the electric field at the area of the specimen surface can be adjusted at will without the optical properties of the objective being changed to a significant degree. Moreover, secondary electrons emanating from the bottom of a pit-like recess in the specimen can thus be detected; this requires a comparatively high voltage across the final electrode 42, for example, 1 kV for a distance of 1 mm from the specimen. Such a voltage, when superposed on the objective voltage, may undesirably affect the optical properties thereof. Moreover, in combination with the final electrode of the objective this additional electrode 42 also has a given lens effect, with the result that the secondary beam has a comparatively large cross-section at the area of the detector surface so that it is prevented that a major part of the beam is radiated back through the opening in the detector.

The final electrode 42 can be subdivided into a number of electrically isolated segments around the optical axis 4. (Such segmentation is not shown in the Figure). The secondary beam can be deflected by applying different voltages to the segments. This can be realized by subdividing the final electrode 42 into two, four or more segments. In the case of two segments a fixed deflection direction is obtained; in the case of four segments the deflection direction can be adjusted at will and in the case of more segments (for example, eight segments) higher-order terms in the deflection field can be reduced, thus reducing undesirable deformation of the secondary beam. The effect thereof is that the secondary beam is directed slightly obliquely through the opening of the objective, so that it is again prevented that a major part of this beam is radiated back through the opening in the detector. The primary beam is not or only hardly affected by such segmentation, because it has an energy which is much higher than that of the secondary beam.

1. A particle-optical apparatus which includes
a particle source for producing a primary beam (22) of electrically charged particles which travel along an optical axis (4) of the apparatus,
a specimen holder for a specimen (18) to be irradiated by means of the apparatus,
a focusing device (14, 16) for forming a focus of the primary beam in the vicinity of the specimen holder by means of electrostatic electrodes,
detection means (6) for detecting electrically charged particles emanating from the specimen in response to the incidence of the primary beam, which detection means are arranged ahead of the focusing device, viewed in the propagation direction of the electrically charged particles in the primary beam,
and an electrostatic final electrode which is arranged directly ahead of the specimen holder, viewed in the propagation direction of the electrically charged particles in the primary beam, characterized in that
the apparatus is provided with power supply means (28) for adjusting a potential difference between the specimen (18) to be irradiated by means of the apparatus and the final electrode.

2. A particle-optical apparatus as claimed in claim 1, in which the final electrode is formed by the electrode (16) of the focusing device (14, 16) which is situated nearest to the specimen holder.

3. A particle-optical apparatus as claimed in claim 1, in which the final electrode is formed by an electrode (42) which is situated between the electrode (16) of the focusing device (14, 16) that is nearest to the specimen holder and the specimen holder, said electrode (42) being rotationally symmetrical around the optical axis (4).

4. A particle-optical apparatus as claimed in claim 2 or 3, in which the final electrode (42) is symmetrically subdivided into a number of electrically isolated segments around the optical axis (4).

5. A particle-optical apparatus as claimed in claim 1, in which the final electrode is formed by an electrode (40) which is situated between the electrode (16) of the focusing device (14, 16) that is nearest to the specimen holder and the specimen holder (18), said final electrode (40) being situated completely to one side of the optical axis (4).
